(19) United States
(12) Patent Application Publication
(10) Pub. No.: US 2024/0297122 A1
(43) Pub. Date: Sep. 5, 2024

(54) SEMICONDUCTOR PACKAGE AND METHOD OF MANUFACTURING A SEMICONDUCTOR PACKAGE

(71) Applicant: Samsung Electronics Co., Ltd., Suwon-si (KR)

(72) Inventors: Hyundong Lee, Suwon-si (KR); Youngmin Kim, Suwon-si (KR); Minji Kim, Suwon-si (KR); Joonseok Oh, Suwon-si (KR); Changbo Lee, Suwon-si (KR)

(21) Appl. No.: 18/592,829

(22) Filed: Mar. 1, 2024

(30) Foreign Application Priority Data
Mar. 2, 2023 (KR) 10-2023-0027966

(51) Int. Cl. H01L 23/538; H01L 23/00; H01L 23/31; H01L 23/498; H01L 25/10; H10B 80/00

(52) U.S. Cl. CPC H01L 23/5386; H01L 23/3128; H01L 23/49811; H01L 23/5385; H01L 24/08; H01L 25/105; H10B 80/00; H01L 24/16; H01L 2224/08225; H01L 2224/16227

(57) ABSTRACT

Provided is a semiconductor package including a first chip, a first chip pad on an upper surface of the first chip, an upper redistribution structure above the first chip, a lowermost via pattern within the upper redistribution structure and non-overlapping with the first chip pad in a vertical direction, and a connection pattern electrically connecting the first chip pad to the lowermost via pattern, wherein the connection pattern overlaps each of the first chip pad and the lowermost via pattern in a vertical direction.

### CROSS-REFERENCE TO RELATED APPLICATION

This application is based on and claims priority under 35 U.S.C. § 119 to Korean Patent Application No. 10-2023-0027966, filed on Mar. 2, 2023, in the Korean Intellectual Property Office, the disclosure of which is incorporated by reference herein in its entirety.

### BACKGROUND

The disclosure relates to a semiconductor package, and more particularly, to a highly integrated semiconductor package.

Recently, in the electronic product market, the demand for portable devices has rapidly increased, and accordingly, miniaturization and weight reduction of electronic components mounted in such electronic products have been continuously required. For miniaturization and weight reduction of electronic components, a semiconductor package mounted thereon is required to have a smaller volume and be able to process high-capacity data.

### SUMMARY

The disclosure provides a semiconductor package with improved yield by controlling errors generated during pattern formation according to large-area exposure and method for manufacturing the same.

According to a first aspect of the disclosure, a semiconductor package includes a first chip, a first chip pad on an upper surface of the first chip, an upper redistribution structure above the first chip, a lowermost via pattern within the upper redistribution structure that does not overlap the first chip pad in a vertical direction, and a connection pattern electrically connecting the first chip pad to the lowermost via pattern, wherein the connection pattern overlaps each of the first chip pad and the lowermost via pattern in a vertical direction.

According to another aspect, a semiconductor package includes a first chip, a plurality of chip pads on an upper surface of the first chip, an upper redistribution structure above the first chip, a plurality of lowermost via patterns located in a lower portion of the upper redistribution structure and extending in a vertical direction, and connection patterns each connecting a corresponding one of the chip pads to a corresponding one of the lowermost via patterns, wherein the upper redistribution structure comprises a first wiring including a first lowermost via pattern of the plurality of lowermost via patterns and a first connection pattern of the connection patterns connecting the first chip pad to the first lowermost via pattern, wherein the first lowermost via pattern does not overlap the first chip pad in the vertical direction, and wherein the first connection pattern extends in a horizontal direction from the first chip pad toward the lowermost via pattern.

According to another aspect, a semiconductor package includes a lower redistribution structure, a plurality of first chips located on the lower redistribution structure, conductive pillars spaced apart from the first chips in a horizontal direction, a molding member surrounding sidewalls of the plurality of first chips and sidewalls of the conductive pillars, an external connection bump located on a lower surface of the lower redistribution structure, an upper redistribution structure located on an upper surface of the molding member, a plurality of second chips mounted on the upper redistribution structure, and a plurality of third chips mounted on the upper redistribution structure, wherein the first chips are bridge chips, each electrically connecting a corresponding one of the second chips to a corresponding one of the third chips, wherein a plurality of chip pads are formed on upper surfaces of each of the plurality of first chips, wherein the upper redistribution structure comprises upper redistribution insulating layers and upper redistribution patterns, wherein the upper redistribution patterns comprise lowermost via patterns located at the lowermost of the upper redistribution patterns and extending in a vertical direction, wherein the upper redistribution structure further comprises connection patterns each connecting a corresponding one of the chip pads to a corresponding one of the lowermost via patterns, wherein the upper redistribution structure comprises a first wiring including a first lowermost via pattern of the plurality of lowermost via patterns, a first chip pad of the chip pads and a first connection pattern of the connection patterns connecting the first chip pad to the first lowermost via pattern, wherein the first lowermost via pattern does not overlap the first chip pad in the vertical direction, and wherein the first connection pattern extends in a horizontal direction from the first chip pad toward the lowermost via pattern.

According to aspects of the disclosure, methods of manufacturing the disclosed semiconductor packages are also provided.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package according to an embodiment;

FIG. 2A is a plan view schematically illustrating a structure in which first chips are accurately aligned on a lower redistribution structure;

FIG. 2B is a plan view schematically illustrating a structure in which first chips are misaligned on a lower redistribution structure;

FIG. 3A is a schematic diagram schematically illustrating a layout of first chip pads and lowermost via patterns according to the arrangement of first chips of FIG. 2A;

FIG. 3B is a schematic diagram schematically illustrating a layout of first chip pads and lowermost via patterns according to the arrangement of the first chips of FIG. 2B;

FIG. 3C is a schematic diagram schematically illustrating connection patterns formed according to the layout of FIG. 2B;

FIG. 4 is a schematic diagram schematically illustrating a connection pattern according to an embodiment;

FIG. 5 is a cross-sectional view illustrating a semiconductor package according to an embodiment; and

FIG. 6 is a cross-sectional view illustrating a semiconductor package according to an embodiment.

### DETAILED DESCRIPTION OF THE EMBODIMENTS

Hereinafter, embodiments will be described in detail with reference to the accompanying drawings. The same reference numerals are used for the same components in the drawings, and duplicate descriptions thereof may be omitted.

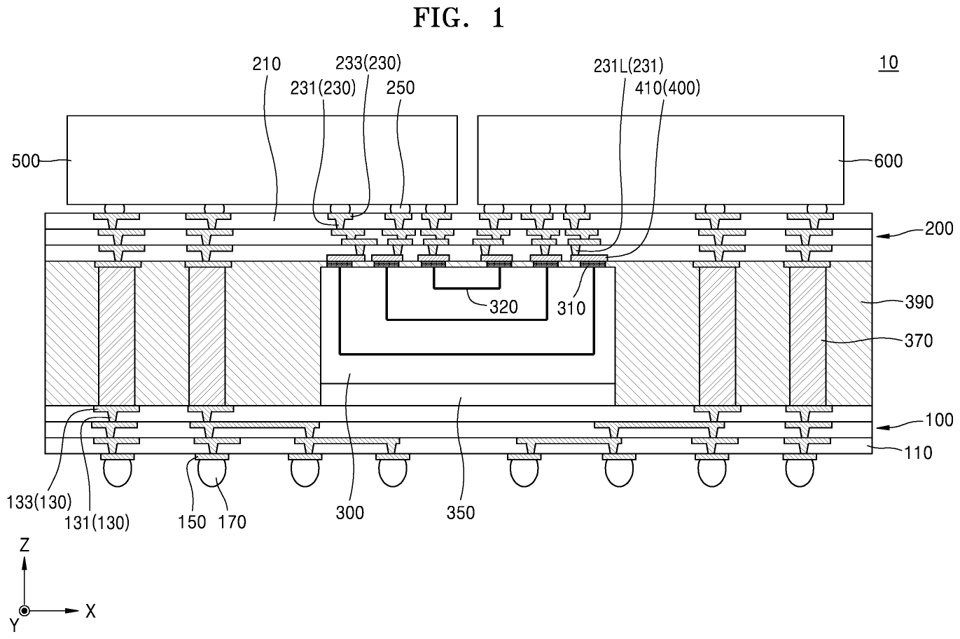

FIG. 1 is a cross-sectional view illustrating a semiconductor package according to an embodiment.

Referring to FIG. 1, a semiconductor package 10 according to the technical idea of the disclosure may include a lower redistribution structure 100, an upper redistribution structure 200, a first chip 300, a second chip 500, a second chip 500, a third chip 600, a molding member 390, and a conductive pillar 370.

The lower redistribution structure 100 may be located under the first chip 300. According to example embodiments, the lower redistribution structure 100 may include lower redistribution insulating layers 110 mutually stacked in the vertical direction Z. The lower redistribution insulating layers 110 may be formed of the same material, such as from, for example, photo imageable dielectric (PID) or photosensitive polyimide (PSPI). The lower redistribution structure 100 may also be referenced as a lower redistribution layer.

In the drawings below, the X-axis direction and the Y-axis direction represent directions parallel to the upper or lower surface of the lower redistribution structure 100 (which may be referred to herein as horizontal directions), and the X-axis direction and the Y-axis direction may be directions perpendicular to each other. The Z-axis direction may indicate a direction perpendicular to the upper or lower surface of the lower redistribution structure 100 (which may be referred to herein as the vertical direction). In other words, the Z-axis direction may be a direction perpendicular to the X-Y plane.

Specifically, in the following drawings, the first horizontal direction, the second horizontal direction, and the vertical direction may be understood as follows. The first horizontal direction may be understood as the X-axis direction, the second horizontal direction may be understood as the Y-axis direction, and the vertical direction may be understood as the Z-axis direction.

The lower redistribution pattern 130 may be provided in the lower redistribution insulating layer 110. The lower redistribution pattern 130 may be formed to extend through the lower redistribution insulating layers 110 in a vertical direction Z from the upper surface to the lower surface of the lower redistribution structure 100. Accordingly, the lower redistribution pattern 130 may serve as an electrical connection (a wiring)penetrating the upper and lower surfaces of the lower redistribution structure 100. It should be appreciated that a plurality of the lower redistribution patterns 130 may be provided with the lower redistribution structure 100, each forming a wiring to provide an electrical connection between the lower surface of the lower redistribution structure 100 and an upper surface of the lower redistribution structure 100, such as between a terminal of the semiconductor package 10 (an external connection bump 170/a lower pad 150) and a conductive pillar 370. The lower redistribution pattern 130 may be a conductor, and be formed of and/or include, for example, a conductive metal such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Bc), gallium (Ga), ruthenium (Ru), and the like, or an alloy thereof, but is not limited thereto. In some embodiments, the lower redistribution pattern 130 may be formed by laminating a metal or an alloy of a metal on a seed layer including C, Ti, titanium nitride, or titanium tungsten.

The lower redistribution pattern 130 may include a lower redistribution line pattern 133 and a lower redistribution via pattern 131. The lower redistribution pattern 130 may have a multilayer structure in which two or more lower redistribution line patterns 133 and lower redistribution via patterns 131 are alternately stacked. It should be appreciated that the cross sectional views of the lower redistribution patterns 130 are simplified views, and that the lower redistribution line patterns 133 may extend in various horizontal directions (in both X and Y directions) to provide various electrical connections as desired per the design of the semiconductor package 10.

The lower redistribution line pattern 133 may have a shape extending in a horizontal direction along at least one surface among upper and lower surfaces of each of the lower redistribution insulating layers 110. The lower redistribution via pattern 131 may have a shape extending through the lower redistribution insulating layer 110 in the vertical direction Z. The lower redistribution via pattern 131 may electrically connect lower redistribution line patterns 133 positioned at different levels in the vertical direction Z.

In some embodiments, at least some of the lower redistribution line patterns 133 may be formed together with some of the lower redistribution via patterns 131 to form an integral body formed of the same material.

In some embodiments, the lower redistribution via pattern 131 may have a tapered shape in which a horizontal width narrows as the level in the vertical direction Z decreases (in the downward direction in FIG. 1). For example, the horizontal width of the lower redistribution via patterns 131 may decrease as the distance from the first chip 300 in the vertical direction Z increases.

The first chip 300 may be located on the upper surface of the lower redistribution structure 100. According to some embodiments, the first chip 300 may be mounted on the lower redistribution structure 100 with the adhesive layer 350. In this case, the upper surface of the first chip 300 may be an active surface (a surface adjacent to a region on which individual semiconductor elements or wiring patterns are formed (i.e., a surface above active regions formed in the semiconductor substrate of the first chip 300 that form transistors)), and the lower surface of the first chip 300 may be an inactive surface (the backside of the first chip 300 which may be formed of the surface of the semiconductor substrate opposite to the surface containing the active regions (i.e., the surface of the semiconductor substrate that is not used to form transistors)). That is, when the first chip 300 is mounted on the lower redistribution structure 100 by the adhesive layer 350, the inactive backside surface may face downward. In this case, the first chip 300 may be electrically connected to external devices via the upper redistribution structure 200.

The adhesive layer 350 may itself be a film having adhesive properties. For example, the adhesive layer 350 may be a double-sided adhesive film. In example embodiments, the adhesive layer 350 may be a material layer in the form of a tape, a liquid coating curing material layer, or a combination thereof. Also, the adhesive layer 350 may include a thermal setting structure, thermal plastic, UV cure material, or a combination thereof. The first adhesive layer 350 may be referred to as a die attach film (DAF) or a non-conductive film (NCF).

In alternative embodiments, the first chip 300 may be mounted on the lower redistribution structure 100 in a flip chip method where the active surface is face down and connected to external devices via the lower redistribution structure 100 through chip connection bumps such as micro bumps. In such embodiments, an underfill material layer surrounding chip connection bumps may be disposed between the first chip 300 and the lower redistribution structure 100. The underfill material layer may be formed of, for example, an epoxy resin formed by a capillary under-fill method.

In some embodiments, the first chip 300 may be a semiconductor chip and may have an integrated circuit formed therein. For example, the first chip 300 may be a logic chip, a memory chip, or a bridge chip. The memory chip may be, for example, a volatile memory chip, such as a dynamic random access memory (DRAM) or a static random access memory (SRAM), or may be a non-volatile memory, chip such as a phase-change random access memory (PRAM), a magnetoresistive random access memory (MRAM), a ferroelectric random access memory (FeRAM), or a resistive random access memory (RRAM).

The logic chip may be, for example, a microprocessor, such as a central processing unit (CPU), a graphics processing unit (GPU), or an application processor (AP), an analog device, or a digital signal processor.

A bridge chip is a chip used to connect different types of semiconductor chips, and may include a process chip, a logic chip, a memory chip, and the like. The bridge chip may, for example, serve as a bridge electrically connecting a logic chip to a memory chip, and may have chip pads 310 formed with a pitch corresponding to a fine pitch of the chip pads of the semiconductor chip(s) to which it is connected to (e.g., the logic chip and the memory chip). Different sets of chip pads 310 may be provided at different regions of the bridge chip and each set may have a pitch designed align with a corresponding one of the chips to which the bridge chip connects (and thus, the pitches and/or alignment of these sets of chip pads may be different from one another). The bridge chip thus operatively connects the different semiconductor chips so that they may communicate with one another (e.g., by communicating electrical signals).

The following description the chip 300 is considered to be a bridge chip, however, the first chip 300 may be any one of the memory chip, logic chip, and bridge chip.

The first chip 300 may include a first chip pad 310 and a wiring pattern 320. The first chip pad 310 may be disposed on the upper surface of the first chip 300. A plurality of first chip pads 310 may be provided, and may be spaced apart from each other in a horizontal direction, typically regularly spaced apart on the active surface in two dimensions.

The wiring patterns 320 may be formed inside the first chip 300 and electrically connect different first chip pads 310 to each other and/or to internal circuits of the first chip 300. Each wiring pattern 320 may be form a wire and be formed of conductive material (e.g., metal) in one or more layers of the first chip 300 (e.g., different conductive (e.g. metal lines) horizontally extending through the bridge chip 300 at different layers may be connected by conductive vias to form a wiring pattern 320 to connect one chip pad 310 to another chip pad 310 (and thus connect chip 500 to chip 600). According to some embodiments, the wiring patterns 320 and first chip pads 320 may form a bridge circuit. The bridge circuit (and more specifically the first chip pads 320) may have a pitch corresponding to a fine pitch of pads formed on each of the different semiconductor chips to which the bridge chip (here, first chip 300) is connected, and may serve as a bridge electrically connecting these different semiconductor chips (e.g., second chip 500 and third chip 600) to each other.

For example, the second chip 500 (e.g., a chip pads (not shown) of the second chip 500)) may be electrically connected to first ends of the wiring patterns 320 (which may terminate at a corresponding chip pads 310) through connection bumps 250 located (with respect to its depiction in FIG. 1) on the right side of the lower surface of the second chip 500 and upper redistribution patterns 230 that are electrically connected to the connection bumps 250. The third chip 600 (e.g., a chip pads (not shown) of the third chip 600)) may be electrically connected to opposite ends of the wiring patterns 320 through the connection bumps 250 located (with respect to its depiction in FIG. 1) on the left side of the lower surface of the third chip 600, the upper redistribution patterns 230 electrically connected to these connection bumps 250. Since both ends of each wiring pattern 320 are electrically connected to each other, the second chip 500 and the third chip 600 may be electrically connected to each other. As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

According to example embodiments, some of the first chip pads 310 may be electrically connected to the second chip 500 through the upper redistribution pattern 230 and the connection bump 250, and other some of the first chip pads 310 may be electrically connected to the third chip 600 through the upper redistribution pattern 230 and the connection bump 250.

Conductive pillars 370 may be spaced apart from the first chip 300 in the first horizontal direction X. The conductive pillar 370 may be a vertical connection conductor for electrically connecting the upper redistribution structure 200 to the lower redistribution structure 100. The conductive pillar 370 may be, for example, a through mold via or a conductive post. The conductive pillar 370 may be formed of, for example, Cu.

The molding member 390 may be configured to surround side surfaces of the first chip 300 and the conductive pillar 370. The molding member 390 may be a homogenous monolithic structure and may be formed of a thermosetting resin, such as an epoxy resin, a thermoplastic resin, such as polyimide, or a resin including a reinforcing material, such as an inorganic filler therein, specifically, Ajinomoto Build-up Film (ABF), FR-4, BT, and the like, but is not limited thereto, and the first molding member 390 may be formed of a molding material, such as an epoxy mold compound (EMC) or a photosensitive material, such as a photoimagable encapsulant (PIE). In some embodiments, a portion of the molding member 390 may be formed of an insulating material such as a silicon oxide layer, a silicon nitride layer, or a silicon oxynitride layer. According to example embodiments, an upper surface of the molding member 390 may have a planarized surface formed through a planarization process.

The upper redistribution structure 200 may be disposed on the upper surface of the molding member 390 and disposed on the upper surface of the first chip 300.

The upper redistribution structure 200 may include upper redistribution insulating layers 210 and upper redistribution patterns 230. The upper redistribution patterns 230 may include interconnected upper redistribution via patterns 231 and upper redistribution line patterns 233 to form wiring of the upper redistribution structure 200. The upper redistribution layers may be formed of the same material. The upper redistribution insulating layers 210 and the upper redistribution patterns 230 may be the same as or similar to the aforementioned lower redistribution insulating layers 110 and the lower redistribution patterns 130, and duplicate descriptions will be omitted.

The upper redistribution via pattern 231 may include the lowermost via pattern 231L. The lowermost via pattern 231L is located at the lowermost part of the upper redistribution via patterns 231 (e.g., formed in the lowermost one of the upper redistribute layers 210) and may be an upper redistribution via pattern formed over the top of the first chip 300.

According to example embodiments, at least one of the first chip pads 310 may not overlap with at least one of the lowermost via patterns 231L in the vertical direction Z. In other words, at least one of the lowermost via patterns 231L may be formed not to face the first chip pad 310 and may be offset in a horizontal direction from a chip pad 310 to which it should be connected. To provide a connection between an offset via pattern 231L and a chip pad 310, a connection pattern 410 may be formed. The connection pattern 410 may be formed

The connection pattern 410 may be configured to electrically connect the lowermost via pattern 231L to the first chip pad 310. Therefore, even when the lowermost via pattern 231L that does not overlap the first chip pad 310 in the vertical direction Z is formed, the first chip pad 310 and the lowermost via pattern 231L may be electrically connected through the connection pattern 410. Accordingly, even if the lowermost via pattern 231L or the first chip pad 310 is formed out of the target position, the lowermost via pattern 231L and the first chip pad 310 may be electrically connected to each other through the connection pattern 410, such that it is possible to minimize signal defects or mismatching of patterns inside the package.

Also, some of the lowermost via patterns 231L or the first chip pads 310 may be formed at normal target positions, while others may be formed outside the target positions (e.g., due to environmental factors causing formation of these lowermost via patterns 231L and/or first chip pads 310 at positions deviating from these target positions). In this case, the connection pattern 410 having substantially the same or similar shape as the first chip pad 310 is simply formed between the normally aligned lowermost via pattern 231L and the first chip pad 310, and the connection pattern 410 between the misaligned lowermost via pattern 231L and the first chip pad 310 may be configured to electrically connect the lowermost via pattern 231L to the first chip pad 310. Reference to a misaligned lowermost via pattern 231L and first chip pad 310 may be understood to refer to lowermost via pattern 231L and the first chip pad 310 that do not overlap each other in a vertical direction Z. The term “offset” may also be used to refer to this misalignment.

According to example embodiments, the connection pattern 410 may have a shape extending in the first horizontal direction X. To connect the horizontally offset first chip pad 310 to the lowermost via pattern 231L, the connection pattern 410 may have a shape extending in a horizontal direction from the first chip pad 310 toward the lowermost via pattern 231L. According to example embodiments, the footprint (i.e., the area occupied from a plan down view) of the connection pattern 410 may be greater than or equal to the footprint of the first chip pad 310.

According to example embodiments, the molding member 390 may surround side surfaces of the first chip pads 310. Accordingly, an upper surface of each of the first chip pads 310 may be exposed with respect to the molding member 390. Accordingly, the connection pattern 410 positioned on the upper surface of each of the first chip pads 310 may be formed. In some examples, the connection patterns 410 may be formed directly on the first chip pads 310 so that each connection pattern 410 contacts a corresponding chip pad 310. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Conventionally, when the first chip pad 310 and the lowermost via pattern 231L are misaligned, that is, when they do not overlap each other in the vertical direction Z and are not electrically connected, problems such as signal failure or performance degradation within the semiconductor package 10 have occurred.

However, in the semiconductor package 10 according to the technical concept of the disclosure, when misalignment between the first chip pad 310 and the lowermost via pattern 231L is expected, the connection pattern 410 may be selectively formed to electrically connect the first chip pad 310 to the lowermost via pattern 231L.

In addition, as the size of the semiconductor package 10 is gradually reduced, patterns are often formed through large-area exposure, and at this time, by the thermal expansion coefficient of the product, the scale change that occurs during the process, and the error that occurs during chip bonding, a deviation may occur between the layout of the exposure mask and the area to be actually exposed. In addition, the deviation may increase further toward the outer portion due to large-area exposure. Accordingly, a number of misalignments may occur between the first chip pad 310 and the lowermost via pattern 231L.

Therefore, to solve the misalignment problem, the productivity of the semiconductor package is reduced because the deviation is calculated and exposure is performed by dividing the area locally.

However, the semiconductor package 10 according to the technical concept of the disclosure predicts misalignment between the first chip pad 310 and the lowermost via pattern 231L through measurement equipment, and connects the misaligned first chip pad 310 and the lowermost via pattern 231L to each other through a connection pattern 410, such that a semiconductor package may be manufactured while maintaining a large-area exposure method, and ultimately productivity of the semiconductor package 10 may be maximized.

The second chip 500 and the third chip 600 may be mounted on the upper redistribution structure 200. The second chip 500 and the third chip 600 may be mounted on the upper redistribution structure 200 through the connection bump 250. According to example embodiments, the second chip 500 and the third chip 600 may be mounted on the upper redistribution structure 200 through the connection bump 250 in a flip chip method. In example embodiments, an underfill material layer covering the connection bump 250 may be disposed between the second chip 500 and the third chip 600 and the upper redistribution structure 200. This is an example, and the manner in which the second chip 500 and the third chip 600 are mounted on the upper surface of the upper redistribution structure 200 is not limited thereto.

According to example embodiments, the second chip 500 and the third chip 600 may be different types of chips. For example, the second chip 500 may be a logic chip and the third chip 600 may be a memory chip, and conversely, the second chip 500 may be a memory chip and the third chip 600 may be a logic chip. Since the logic chip and the memory chip may be the same as or similar to those described above, a detailed description thereof will be omitted.

The external connection bump 170 may be located on the lower pad 150 formed on the lower surface of the lower redistribution structure 100. The external connection bump 170 may be a terminal of the semiconductor package 10 and may be electrically connected to an external device, for example, a motherboard. The external connection bump 170 may be electrically connected to the lower pad 150. The external connection bumps 170 may be electrically connected to the lower redistribution patterns 130 through the lower pads 150. The external connection bump 170 (e.g., a solder ball or equivalent bump) may electrically and physically connect the semiconductor package 10 to an external device. The external connection terminal 170 may include at least one of a conductive material such as solder, tin (Sn), silver (Ag), copper (Cu), and aluminum (Al).

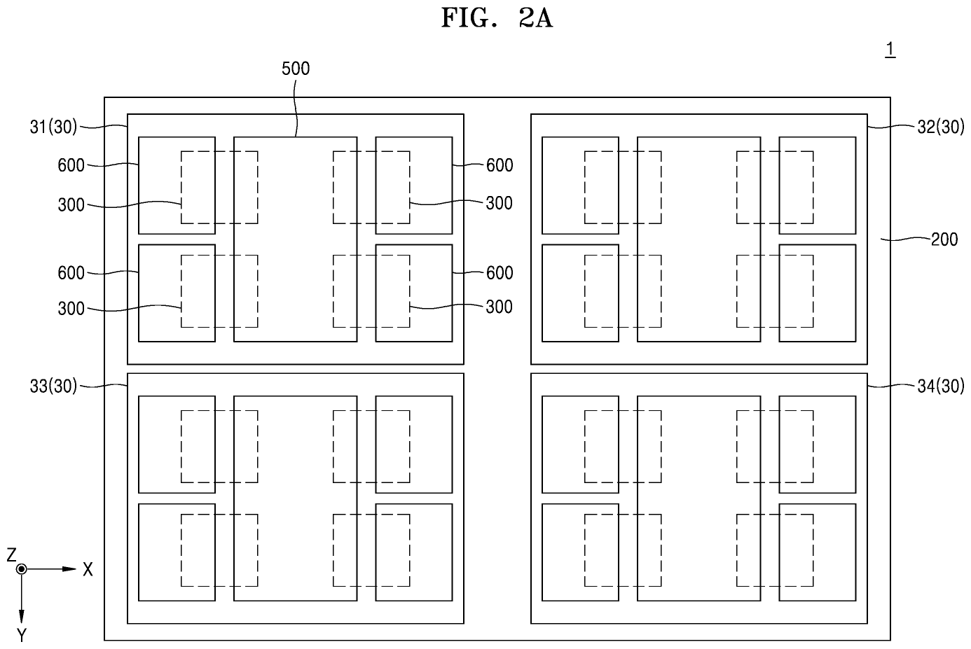

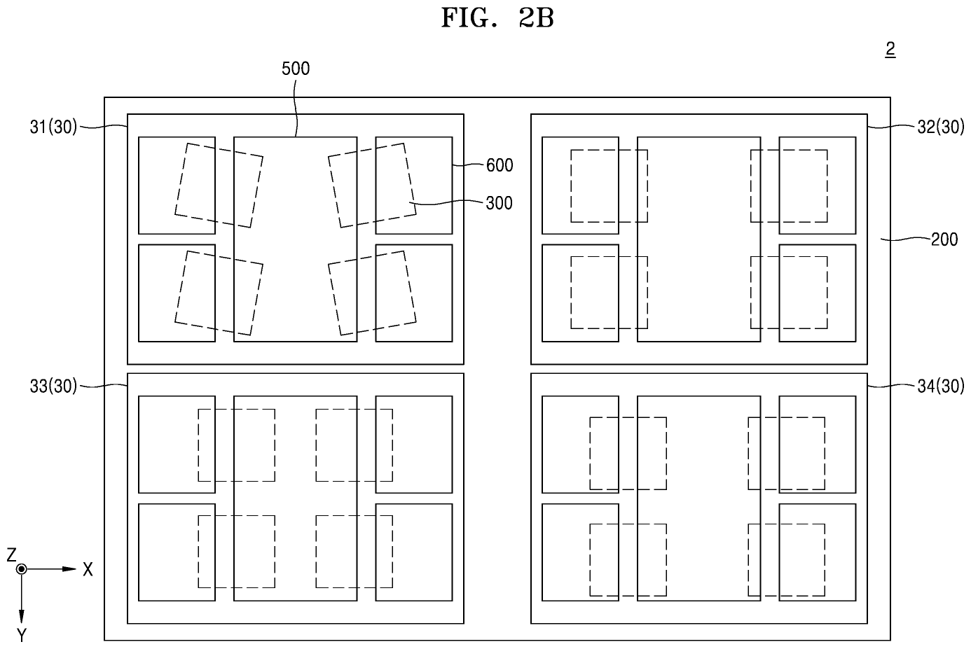

FIG. 2A is a plan view schematically illustrating a structure in which first chips are accurately aligned on a lower redistribution structure. FIG. 2B is a plan view schematically illustrating a structure in which first chips are misaligned on a lower redistribution structure.

Referring to FIGS. 2A and 2B, the semiconductor packages 1 and 2 may include a plurality of units 30. For example, the semiconductor packages 1 and 2 may include a first unit 31, a second unit 32, a third unit 33, and a fourth unit 34. In some examples, each unit 30 may form a separate semiconductor package, such as semiconductor packages 10, 11 and/or 12 described herein. For example, the semiconductor packages 1 and 2 may be cut in a vertical and horizontal directions to separate the units 30 from one another).

Each of the plurality of units 30 may include a plurality of semiconductor chips 300, 500 and 600. For example, the first unit 31 may include four first chips 300, one second chip 500, and four third chips 600. According to embodiments, the first unit 31 includes a second chip 500 as one logic chip and four third chips 600 as memory chips, and include four first chips 300 as bridge chips, each electrically connecting the second chip 500 to a corresponding third chip 600. In this case, the first chips 300 may be positioned at a lower level than the second chip 500 and the third chip 600 in the Z-axis direction.

In addition, in FIGS. 2A and 2B, each of the units 31, 32, 33, and 34 is shown as having the same configuration, but the invention is not limited thereto, and different units 30 may include different combinations of configurations of semiconductor chips.

The semiconductor package 1 of FIG. 2A shows an example in which the plurality of first chips 300 are precisely formed at target positions, and the second chip 500 and the third chips 600 are formed thereon. On the other hand, the semiconductor package 2 of FIG. 2B shows an example in which the plurality of first chips 300 are formed with deviations rather than formed at the target position. In this case, the first chips 300 respectively formed in the first unit 31, the second unit 32, the third unit 33, and the fourth unit 34 may have different deviations. That is, the positional deviation of the first chips 300 formed in the first unit 31 may be different from the positional deviation of the first chips 300 formed in the second unit 32. For example, as shown in FIG. 2B, the first chips 300 formed on the first unit 31 may have a rotational deviation relative to the Z-axis compared to the target position, and the first chips 300 formed on the second unit 32 may have a deviation relative to the X-axis direction (and/or Y-axis direction) compared to the target position. In addition, the first chips 300 formed on the third unit 33 may also have a deviation along the X-axis direction (and/or Y-axis direction) compared to the target position. At this time, the first chips 300 formed on the second unit 32 may have a positive deviation relative to the target position in the X-axis direction (and/or Y-axis direction), and the first chips 300 formed in the third unit 33 may have a negative deviation relative to the target position in the X-axis direction (and/or Y-axis direction). The first chips 300 formed in the fourth unit 34 may have a deviation along a diagonal direction compared to the target position.

Deviations formed in each of the first to fourth units 31, 32, 33, and 34 may be caused by differences in thermal expansion coefficients between components, scale changes according to process progress, bonding accuracy, and the like. In addition, each unit 30 may have a different deviation.

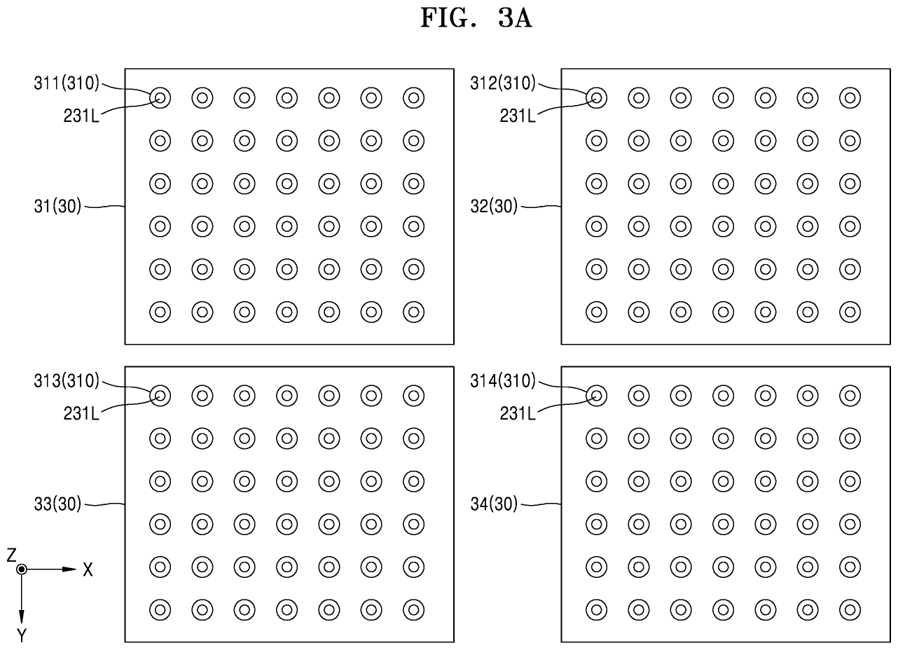

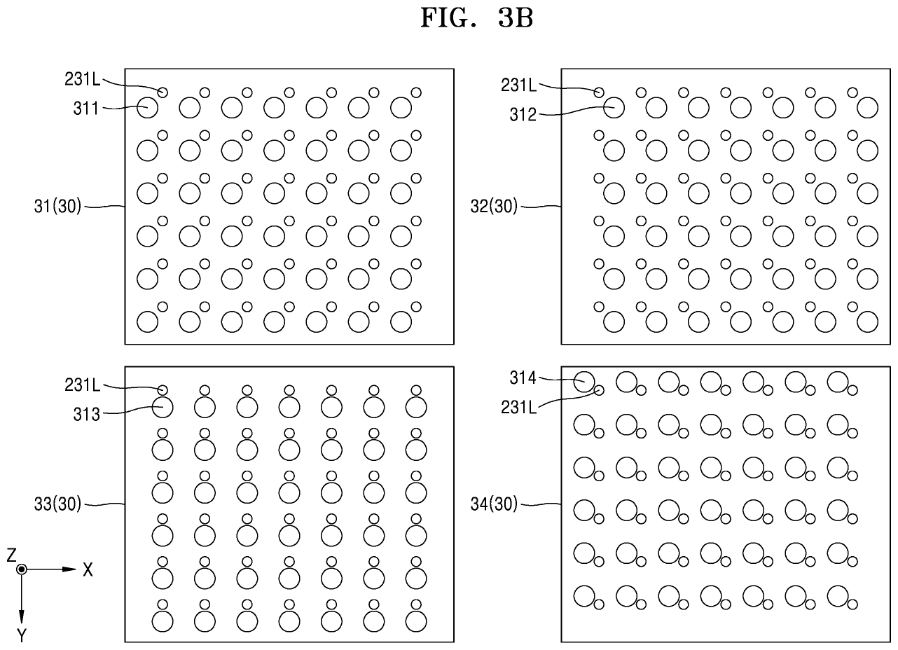

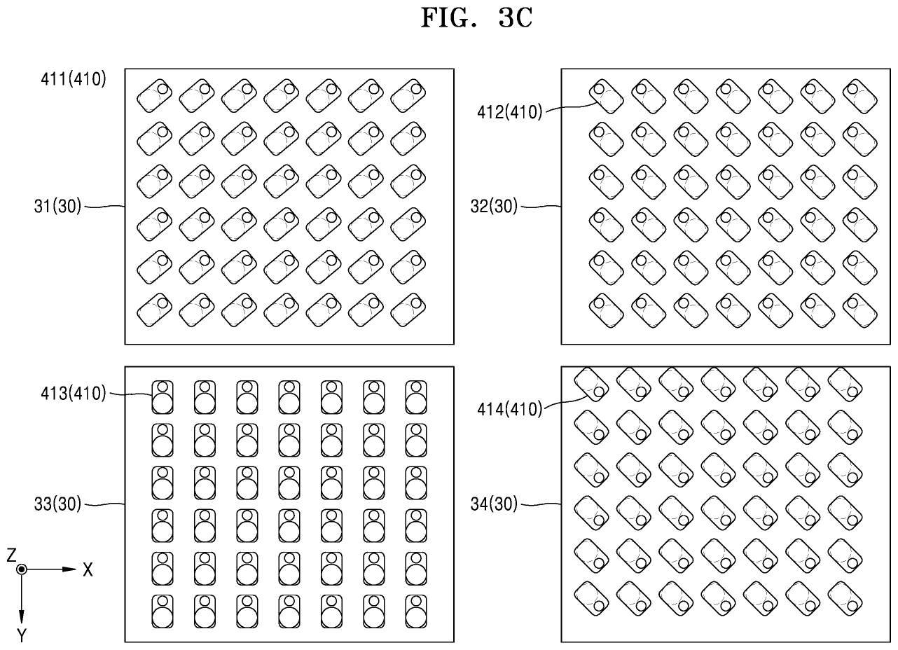

Since the plurality of units 30 may have different deviations from each other, it may be more difficult to control alignment errors when large-area exposure is performed. For example, the upper redistribution structure 200 to the lower redistribution structure 100 may be formed using such large-area exposure and may include such alignment errors. Moreover, the dispersion of the deviations may increase as the exposure area increases. However, as described above with reference to FIG. 1, the alignment error may be compensated through the connection pattern 410 (see FIG. 1). The shape and characteristics of the connection pattern 410 will be described in detail with reference to FIGS. 3A to 3C.

FIG. 3A is a schematic diagram schematically illustrating a layout of first chip pads and lowermost via patterns according to the arrangement of first chips of FIG. 2A. FIG. 3B is a schematic diagram schematically illustrating a layout of first chip pads and lowermost via patterns according to the arrangement of the first chips of FIG. 2B. FIG. 3C is a schematic diagram schematically illustrating connection patterns formed according to the layout of FIG. 2B.

Referring to FIG. 3A, as the first chips 300 (see FIG. 2A) are precisely positioned at the target location, both the lowermost via patterns 231L each overlap a corresponding the first chip pad 310 in the vertical direction Z. This ideal positioning may be identical in all of the first to fourth units 31, 32, 33, and 34.

On the other hand, referring to FIG. 3B, as the first chips 300 (see FIG. 2B) are incorrectly positioned at the target location, at least some of the lowermost via patterns 231L do not overlap with a corresponding first chip pad 311 in the vertical direction Z.

Specifically, as the first chips 300 are positioned with a deviation from the target position in the first unit 31, the first chip pad 311 may be located at the lower left side of the lowermost via pattern 231L. In addition, as the first chips 300 in the second unit 32 are positioned with a deviation from the target position, the first chip pad 312 may be positioned at the right lower end of the lowermost via pattern 231L. As the first chips 300 in the third unit 33 are positioned with a deviation from the target position, the first chip pad 313 may be located at the lower end of the lowermost via pattern 231L. As the first chips 300 in the fourth unit 34 are positioned with a deviation from the target position, the first chip pad 314 may be positioned at the top left of the lowermost via pattern 231L.

As such, each of the units 30 has a different deviation due to the diversity of the deviation of the first chips 300 formed in each of the plurality of units 30, and accordingly, relative positions between the first chip pad 310 and the lowermost via pattern 231L may be different between each of the units 30. Specifically, an intermediate structure of the lower redistribution structure 100, the conductive pillar 370, the molding member 390 and the first chips 300 may be formed, and after forming this intermediate structure, the upper redistribution layer 200 may be formed thereon by sequentially depositing and patterning the insulating layers of the upper redistribution layer 200 on this intermediate structure. The patterning of the insulating layers of the upper redistribution layer 200 may be performed by selective etching using one or more exposure masks formed by photolithographic exposure of a photoresist (PR). When the position of the exposure mask is fixed, the position where the lowermost via pattern 231L is formed may be fixed. However, when the first chip 300 is positioned to have a deviation from the target position (the desired position selected in the product design process), the first chip pads 311, 312, 313, and 314 attached to the upper surface of the first chip 300 may also be positioned to have a deviation from their target position. And, due to the positional deviation of the first chip pads 311, 312, 313, and 314, the first chip pads 311, 312, 313, and 314 and the lowermost via patterns 231L may not overlap each other along the vertical direction Z.

Referring to FIG. 3C, connection patterns 411, 412, 413, and 414 connecting the first chip pad 310 to the lowermost via pattern 231L may be formed to have different shapes, dimensions and/or different extending directions for each unit 30. However, within each unit, the connection patterns 411, 412, 413, and 414 may have the same shape, dimensions and/or same extending direction. For example, in the first unit 31, all of the connection patterns 411 may have the same shape and extend from the lower left to the upper right, and in the second unit 32, all of the connection patterns 412 may have the same shape and extend from a right lower end toward a left upper end. In addition, in the third unit 33, all of the connection patterns 413 may have the same shape and extend from the lower end toward the upper end, and in the fourth unit 34, all of the connection patterns 414 may have the same shape and extend from an upper left corner toward a lower right corner. As such, connection patterns 411, 412, 413, and 414 having different shapes and/or extending directions may be formed for each unit to compensate for the positional deviation of the first chip(s) 300 of each unit 30 and/or deviations from the target positions of the lowermost via pattern 231L (e.g., resulting from large-area exposure). In some examples, each unit 30 may correspond to the connection patterns 410 included in all wirings the wirings of the upper redistribution layer 200 that are connected to a single logic chip 500. In some examples, each unit 30 corresponds to the connection patterns 410 of a package (e.g., each unit 31, 32, 33 and 34 forms a package 10, 11 or 12 and are later separated from one another by cutting semiconductor package 1, 2).

Thus, even if misalignment with different deviations occurs in the plurality of units 30 in the case of using large-area exposure, the first chip pad 310 and the lowermost via pattern 231L may be electrically connected to each other by forming a connection pattern 410 suitable for each variation.

That is, even if misalignment between the first chip pad 310 and the lowermost via pattern 231L occurs in different ways within the semiconductor package 2, by forming the connection pattern 410 corresponding to the misalignment, defects due to the misalignment may be minimized. For example, in the manufacturing process described herein, all or part of a first semiconductor package (like semiconductor package 2) may be formed (e.g., to at least form of the lowermost via pattern 231L on an intermediate structure as described herein) and, for each unit 30, the misalignment between the lowermost via pattern 231L and the corresponding first chip pads 310 may be determined. Then, the design of the upper redistribution layer 200 may be modified to provide connection patterns 410 that extend between the actual positions (as determined by manufacturing the initially designed package) to compensate for deviations from target positions of the first chip pads and/or lowermost via pattern 231L. Subsequent packages 2 may be thus manufactured according to this modified design including the connection patterns 410 to connect offset lowermost via pattern 231L and the corresponding first chip pads 310 that would otherwise not be connected.

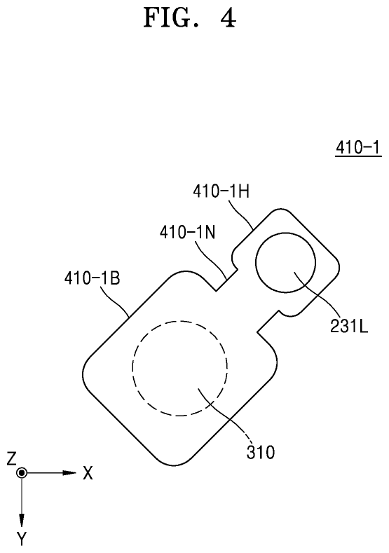

According to example embodiments, the connection pattern 410 may have a shape having a uniform width when viewed in the vertical direction Z. However, the disclosure is not limited thereto, and may have various shapes as will be described later with reference to FIG. 4.

FIG. 4 is a schematic diagram schematically illustrating a connection pattern according to an embodiment. Hereinafter, repetitive detail of the connection pattern 410 described with reference to FIG. 3C and the connection pattern 410-1 of FIG. 4 will be omitted and the differences will be mainly described.

Referring to FIG. 4, a connection pattern 410-1 may include a body 410-1B, a neck 410-1N, and a head 410-1H. According to example embodiments, the connection pattern 410-1 may electrically connect a first chip pad 310 to a lowermost via pattern 231L. To overlap the first chip pad 310 and the lowermost via pattern 231L in the vertical direction Z, the footprint of the connection pattern 410-1 may encompass the footprints of each of the first chip pad 310 and the lowermost via pattern 231L (i.e., overlap each in g the vertical direction Z). Specifically, the connection pattern 410-1 may cover (and contact) the upper surface of the first chip pad 310 through the body 410-1B and while head 410-1H may extend below (and contact)r the lower surface of the lowermost via pattern 231L.

At this time, the body 410-1B and the head 410-H may be connected to each other by the neck 410-1N. The neck 410-1N may have a narrower width than the head 410-1H and the body 410-1B. Accordingly, when viewed in the vertical direction Z, the connection pattern 410-1 may have a narrow width between the first chip pad 310 and the lowermost via pattern 231L.

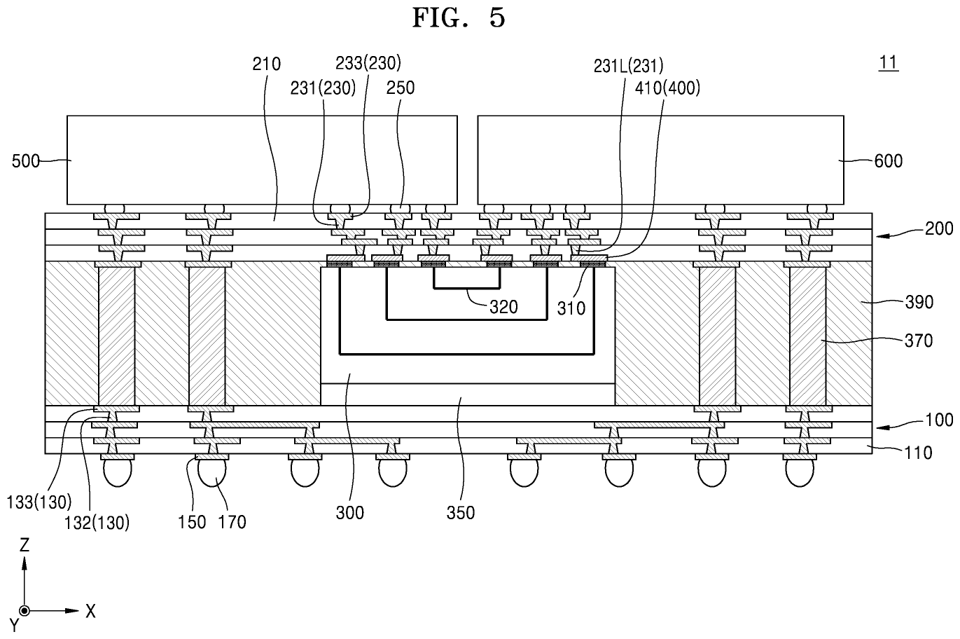

FIG. 5 is a cross-sectional view illustrating a semiconductor package according to an embodiment. Hereinafter, repetitive detail of the semiconductor package 10 described with reference to FIG. 1 and the semiconductor package 11 of FIG. 5 may be omitted and the differences will be mainly described.

Referring to FIG. 5, the semiconductor package 11 may include a lower redistribution structure 100. The lower redistribution structure 100 may include a lower redistribution pattern 130 and a lower redistribution insulating layer 110. The lower redistribution pattern 130 may include a lower redistribution via pattern 132 and a lower redistribution line pattern 133. The lower redistribution via pattern 132 may have a shape in which its horizontal width increases as the level in the vertical direction Z decreases (i.e., the horizontal width increases in the downward direction with respect to FIG. 5). That is, the lower redistribution via pattern 132 may have a tapered shape in which a horizontal width increases as it moves away from the first chip 300 in the vertical direction Z. Conversely, the upper redistribution via pattern 231 of the upper redistribution structure 200 may have a shape in which its horizontal width decreases as the level in the vertical direction Z decreases (i.e., the horizontal width decreases in the downward direction with respect to FIG. 5). The upper redistribution via pattern 231 may have a tapered shape in which a horizontal width increases as it moves away (upwardly) from the first chip 300 in the vertical direction Z.

When the semiconductor package 11 is manufactured by a chip-first process, the lower redistribution via pattern 132 may have a shape in which a horizontal width increases as the level in the vertical direction Z decreases. Accordingly, the lower redistribution via pattern 132 may have sidewalls that slope opposite to that of the upper redistribution via pattern 231. For example, the semiconductor package 11 may be formed by first forming molding 390 surrounding the first chip(s) 300 and then forming conductive pillars 370 therein. Then, the lower redistribution structure 100 is formed on this intermediate product by sequentially depositing and patterning the redistribution insulating layers 110 (e.g., as described herein with respect to the upper redistribution structure 200). It will be appreciated that the patterned redistribution insulating layers 110 (and the patterned layers in the upper redistribution pattern 200) form vias and trenches in which the conductive material is formed to form the wiring of the redistribution structures 100 and 200 (i.e., the lower and upper redistribution patterns 130 and 230). After forming the lower redistribution structure 100 on this intermediate product, this subsequently formed intermediate product (molding 390 surrounding the first chip(s) 300, with conductive pillars 370 and the lower redistribution structure 100 thereon) is flipped (rotated 180 degrees) and then the upper redistribution pattern 200 is formed thereon.

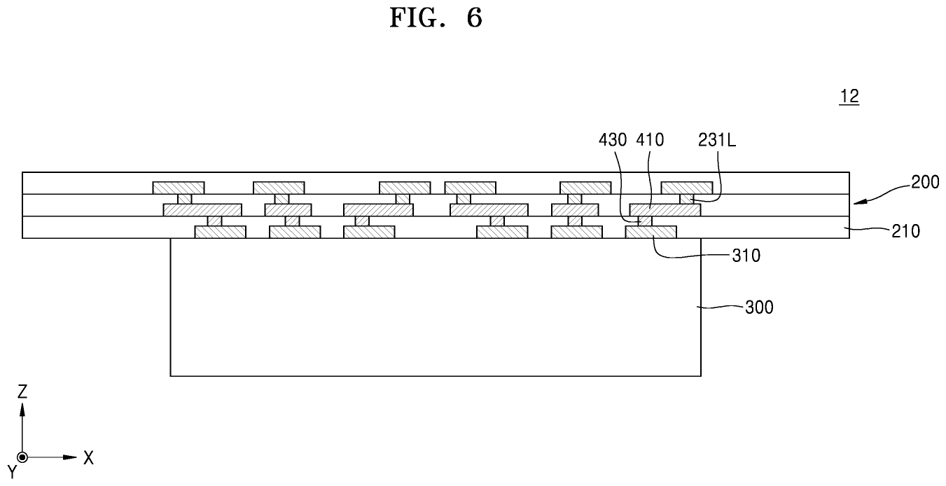

FIG. 6 is a cross-sectional view illustrating a semiconductor package according to an embodiment. Hereinafter, repetitive detail of the semiconductor package 10 described with reference to FIG. 1 and the semiconductor package 12 of FIG. 6 may be omitted and the differences will be mainly described.

Referring to FIG. 6, the semiconductor package 12 may include a first chip 300 and an upper redistribution structure 200 positioned on the first chip 300. In some embodiments, sidewalls chip pads 310 of the first chip 300 may be covered by a redistribution structure (e.g., redistribution structure 200).

According to example embodiments, at least one of the first chip pads 310 may not overlap with at least one of the lowermost via patterns 231L in the vertical direction Z. The connection pattern 410 may be configured to electrically connect the lowermost via pattern 231L to the first chip pad 310.

According to example embodiments, the first chip pad 310 may be electrically connected to the connection pattern 410 through the connection via 430. The connection pattern 410 may be electrically connected to the lowermost via pattern 231L. Accordingly, the first chip pad 310 may be electrically connected to the lowermost via pattern 231L through the connection via 430 and the connection pattern 410.

According to example embodiments, the connection via 430 may be positioned between the first chip pad 310 and the connection pattern 410 and extend along the vertical direction Z.

In electrically connecting the first chip pad 310 and the lowermost via pattern 231L, in the semiconductor package 12 of FIG. 6, the first chip pad 310 and the lowermost via pattern 231L may be electrically connected to each other through the connection pattern 410 and the connection via 430 positioned below the connection pattern 410.

The connection patterns 410 in the embodiments described herein may have dimensions in both the X and Y directions that are larger than the width of the wiring (the upper redistribution patterns 230) of the upper redistribution structure 200 to which it is connected. Thus, the dimensions of each connection pattern 410 in both the X and Y directions may each be greater than the width of the upper redistribution line patterns 233 and the width of upper redistribution via patterns 231 to which it is connected. It should be understood that the width of a wiring (such as the width of upper redistribution line patterns 233 and the width of the connection pattern 410) is in a direction perpendicular to the extending direction of the wiring, where the extending direction is the path of the wiring (e.g., corresponding to the current path provided by the wiring). As the path of a wiring may not be linear, it should be appreciated that the extending direction of a wiring may change along the length of the wiring (and likewise, the width direction changes). For a linear segment of wiring, the length of the wiring segment in the extending direction is greater than its width (perpendicular to that extending direction).

Furthermore, the lowermost insulating layer 210 of the upper redistribution structure 200 that is formed directly over the first chips 300 may only include connection patterns 410. Furthermore, the connection patterns 410 may have horizontal widths that are not significantly different from each other. For example, a maximum horizontal width (or horizontal length) of a connection pattern 410 (in a corresponding horizontal direction A) may be no more than three times or no more five times the width of that connection pattern 410 in a horizontal direction perpendicular to horizontal direction A.

Furthermore, the connection patterns 410 may not be connected to any other conductor in the same horizontal layer of the upper redistribution structure 200. Thus, all electrical connections to the connection patterns 410 may be provided by a conductor contacting the top or bottom surface of a connection pattern 410, such as (as described herein) contact with lowermost via pattern 231L at the top surface of a connection pattern 410, contact with a chip pad 310 at a bottom surface of a connection pattern 410, or contact with connection via 430 at a bottom surface of a connection pattern 410. Thus, with respect to a horizontal layer of the upper redistribution structure 200 at a level including the connection patterns 410 (e.g., as shown in FIG. 3C), each connection pattern 410 forms a conductive island within the corresponding insulating layer, such that the connection patterns 410 are isolated from one another and not connected to any other conductor (e.g., not directly connected to any upper redistribution line patterns 233) within this horizontal layer. While the disclosure has been particularly shown and described with reference to embodiments thereof, it will be understood that various changes in form and details may be made therein without departing from the spirit and scope of invention.

1. A semiconductor package comprising:
a first chip;
a first chip pad on an upper surface of the first chip;
an upper redistribution structure above the first chip;
a lowermost via pattern within the upper redistribution structure that does not overlap the first chip pad in a vertical direction; and
a connection pattern electrically connecting the first chip pad to the lowermost via pattern,
wherein the connection pattern overlaps each of the first chip pad and the lowermost via pattern in a vertical direction.

2. The semiconductor package of claim 1, wherein the connection pattern has a shape extending in a horizontal direction from the first chip pad toward the lowermost via pattern.

3. The semiconductor package of claim 1, wherein the connection pattern has a substantially uniform width when viewed in a vertical direction.

4. The semiconductor package of claim 1, wherein the connection pattern has a narrow width between the first chip pad and the lowermost via pattern when viewed in a vertical direction.

5. The semiconductor package of claim 1,
wherein the connection pattern further comprises a connection via, and
wherein the connection via electrically connects the first chip pad to the connection pattern.

6. The semiconductor package of claim 1, further comprising:
a lower redistribution structure located under the first chip;
a conductive pillar spaced apart from the first chip in a horizontal direction and electrically connecting the upper redistribution structure to the lower redistribution structure; and
a molding member surrounding the first chip and the conductive pillar.

7. The semiconductor package of claim 6,
wherein the lower redistribution structure comprises a lower redistribution via pattern extending in a vertical direction, and
wherein the lower redistribution via pattern has a shape in which a horizontal width of the lower redistribution via pattern narrows as a level in the vertical direction decreases.

8. The semiconductor package of claim 6,
wherein the lower redistribution structure comprises a lower redistribution via pattern extending in a vertical direction, and
wherein the lower redistribution via pattern has a shape in which a horizontal width of the lower redistribution via pattern increases as a level in the vertical direction decreases.

9. The semiconductor package of claim 1, wherein the first chip is a bridge chip electrically connecting a plurality of chips to each other connected to a bottom surface of the upper redistribution structure.

10. The semiconductor package of claim 9,
wherein one of the plurality of chips is a logic chip, and
wherein another one of the plurality of chips is a memory chip.

11. A semiconductor package comprising:
a first chip;
a plurality of chip pads on an upper surface of the first chip;
an upper redistribution structure above the first chip;
a plurality of lowermost via patterns located in a lower portion of the upper redistribution structure and extending in a vertical direction; and
connection patterns each connecting a corresponding one of the chip pads to a corresponding one of the lowermost via patterns;
wherein the upper redistribution structure comprises a first wiring including a first lowermost via pattern of the plurality of lowermost via patterns and a first connection pattern of the connection patterns connecting the first chip pad to the first lowermost via pattern,
wherein the first lowermost via pattern does not overlap the first chip pad in the vertical direction, and
wherein the first connection pattern extends in a horizontal direction from the first chip pad toward the lowermost via pattern.

12. The semiconductor package of claim 11,
wherein the first connection pattern overlaps each of the first chip pad and the first lowermost via pattern in a vertical direction, and
wherein the first connection pattern has a substantially uniform width with respect to a plan view as viewed in the vertical direction.

13. The semiconductor package of claim 11,
wherein the first connection pattern overlaps each of the first chip pad and the first lowermost via pattern in a vertical direction, and
wherein the first connection pattern has a first portion overlapping the first chip pad in the vertical direction, a second portion overlapping the first lowermost via pattern in the vertical direction, and an intermediate portion connecting the first portion and the second portion, and
wherein, with respect to a plan view as viewed in the vertical direction, the intermediate portion has a relatively narrow width as compared to the first portion and the second portion.

14. The semiconductor package of claim 11, further comprising:
a lower redistribution structure under the first chip;
a conductive pillar disposed horizontally apart from the first chip and electrically connecting the upper redistribution structure to the lower redistribution structure; and
a molding member surrounding the first chip and the conductive pillar.

15. The semiconductor package of claim 14, wherein the molding member surrounds side surfaces of each of the chip pads.

16. The semiconductor package of claim 11, wherein the first chip is a bridge chip electrically connecting a plurality of chips to each other, the bridge chip being attached to a lower surface of the upper redistribution structure.

17. The semiconductor package of claim 11, further comprising a
connection via connecting the first chip pad to the first connection pattern.

18. A semiconductor package comprising:
a lower redistribution structure;
a plurality of first chips located on the lower redistribution structure;
conductive pillars spaced apart from the first chips in a horizontal direction;
a molding member surrounding sidewalls of the plurality of first chips and sidewalls of the conductive pillars;
an external connection bump located on a lower surface of the lower redistribution structure;
an upper redistribution structure located on an upper surface of the molding member;
a plurality of second chips mounted on the upper redistribution structure; and
a plurality of third chips mounted on the upper redistribution structure,
wherein the first chips are bridge chips, each electrically connecting a corresponding one of the second chips to a corresponding one of the third chips,
wherein a plurality of chip pads are formed on upper surfaces of each of the plurality of first chips,
wherein the upper redistribution structure comprises upper redistribution insulating layers and upper redistribution patterns,
wherein the upper redistribution patterns comprise lowermost via patterns located at the lowermost of the upper redistribution patterns and extending in a vertical direction,
wherein the upper redistribution structure further comprises connection patterns each connecting a corresponding one of the chip pads to a corresponding one of the lowermost via patterns,
wherein the upper redistribution structure comprises a first wiring including a first lowermost via pattern of the plurality of lowermost via patterns, a first chip pad of the chip pads and a first connection pattern of the connection patterns connecting the first chip pad to the first lowermost via pattern,
wherein the first lowermost via pattern does not overlap the first chip pad in the vertical direction, and
wherein the first connection pattern extends in a horizontal direction from the first chip pad toward the lowermost via pattern.

19. The semiconductor package of claim 18,
wherein the first connection pattern has a first portion overlapping the first chip pad in the vertical direction, a second portion overlapping the first lowermost via pattern in the vertical direction, and an intermediate portion connecting the first portion and the second portion, and
wherein, with respect to a plan view as viewed in the vertical direction, the intermediate portion has a relatively narrow width as compared to the first portion and the second portion.

20. The semiconductor package of claim 18,
wherein the lower redistribution structure comprises a lower redistribution via pattern extending in a vertical direction,
wherein the lower redistribution via pattern has a shape in which a horizontal width of the lower redistribution via pattern increases as a level in the vertical direction decreases, and
wherein the second chips are a logic chips, and the third chips are memory chips.

21-24. (canceled)
